(19) United States
(12) Patent Application Publication
(10) Pub. No.: US 2025/0079075 A1
(43) Pub. Date: Mar. 6, 2025

(54) Transformer Winding and Method for Constructing Transformer Winding

(71) Applicant: Eaton Intelligent Power Limited, Dublin 4 (IE)

(72) Inventors: Jianxiong Yu, Shanghai (CN); Cheng Luo, Shanghai (CN); Jiajie Duan, Shanghai (CN); Cheng Wang, Shanghai (CN)

(21) Appl. No.: 18/816,070

(22) Filed: Aug. 27, 2024

(30) Foreign Application Priority Data
Sep. 5, 2023 (CN) 202311140567.4

(51) Int. Cl. H01F 27/32; H01F 27/28; H01F 41/02

(52) U.S. Cl. CPC H01F 27/32; H01F 27/2885; H01F 41/02

(57) ABSTRACT

Provided are a transformer winding and a method for constructing a transformer winding. The transformer winding includes: a winding conductor having a ring structure; a first insulating layer wrapped on a surface of the winding conductor formed by winding; a conductor tape attached in an unclosed surrounding manner to a surface of the first insulating layer along a circumferential direction of the first insulating layer, where the conductor tape is attached to a position having a minimum value of a leakage flux on the surface of the first insulating layer; a first shielding layer attached to the surface of the first insulating layer with the conductor tape attached thereto; a second insulating layer cast outside the first shielding layer; and a second shielding layer wrapped on an outer surface of the second insulating layer.

### CROSS-REFERENCE TO PRIORITY APPLICATION

This application claims priority to Chinese Patent Application No. 202311140567.4, filed Sep. 5, 2023, the content of which is hereby incorporated herein by reference in its entirety.

### TECHNICAL FIELD

The present inventive concept relates to the field of transformers, and in particular, relates to a transformer winding and a method for constructing a transformer winding.

### BACKGROUND

Medium voltage solid-state transformers are gradually becoming a preferred solution for large-scale new energy gathering, data center power supply, super charging, and other fields due to their outstanding advantages such as high efficiency, high density, and rich control freedom. These advantages mainly benefit from the application of high-frequency isolation transformers in systems. As operating frequencies increase, transformers can achieve higher power densities. However, medium voltage applications also require isolation levels of transformers, which must be able to withstand grid over-voltage caused by grid faults or meteorological events. Conventional power frequency transformers rely more on insulation over-design and insulation margin to ensure their voltage withstanding capability, while the high power densities of high-frequency transformers lead to a lack of insulation margin, uneven distribution of electric fields, and severe local field strength distortion of the transformers. Therefore, how to design a transformer with a high isolation level under a high power density has become a major challenge in the field of medium voltage solid-state transformers.

In order to solve the uneven and distorted distribution of electric fields, semi-conductive materials are often used as shielding layers in medium voltage high-frequency transformers to achieve uniform and softened electric fields. The shielding layers include an inner shielding layer close to the potential of a winding and an outer shielding layer outside an insulating casting layer. The inner shielding layer can not only increase the curvature radius of a field source to soften the electric field, but also eliminate the problem of partial discharge caused by casting defects inside the winding, thereby improving the yield of a casting process. In order to ensure insulation between turns of a Litz wire winding and effective potential connection of the inner shielding layer, the potential connection of the shielding layer is often achieved by sticking a conductor tape outside the Litz wire winding and leading the conductor tape out. Such a method can achieve potential connection of the inner shielding layer without damaging the insulation of the Litz wire winding. However, the conductor tape inevitably introduces additional eddy current loss under high-frequency leakage flux, and the loss occurring within the insulating layer will directly affect the hottest spot temperature rise of the transformer, thereby accelerating aging and shortening insulation life. Therefore, it is significant in practical applications to quantify the additional loss and minimize the additional loss as much as possible while ensuring potential contact.

### SUMMARY

Based on the above problems of the prior art, the present inventive concept provides a transformer winding, including: a winding conductor having a ring structure; a first insulating layer wrapped on a surface of the winding conductor formed by winding; a conductor tape attached in an unclosed surrounding manner to a surface of the first insulating layer along a circumferential direction of the first insulating layer, where the conductor tape is attached to a position having a minimum value of a leakage flux on the surface of the first insulating layer; a first shielding layer attached to the surface of the first insulating layer with the conductor tape attached thereto; a second insulating layer cast outside the first shielding layer; and a second shielding layer wrapped on an outer surface of the second insulating layer.

In some embodiments, the shortest path with the minimum leakage flux on the surface of the first insulating layer is selected as an attachment path.

In some embodiments, the conductor tape is attached to an inner surface of the first insulating layer.

In some embodiments, the conductor tape is attached to an outer surface of the first insulating layer.

In some embodiments, a loss of the conductor tape is:

$${P}_{loss} = \frac{{σ}_{cop} \cdot {W}_{cop} \cdot {D}_{cop}^{3}}{12} {\int }_{0}^{{L}_{cop}} 〈 \overline{{( \frac{\partial {B}_{{x}_{i}}}{\partial t} )}^{2}} 〉 dx$$

where σ_{cop} is a conductivity of the conductor tape, W_{cop} is a width of the conductor tape, D_{cop} is a thickness of the conductor tape, L_{cop} is a length of the conductor tape, an Bₓ_{ᵢ} is a leakage flux intensity at the position of the conductor tape.

In some embodiments, the conductor tape is a copper foil tape or aluminum foil tape with adhesion.

In some embodiments, the first insulating layer includes an epoxy resin coated on the outside of the winding conductor and an insulating tape semi-overlap wound on a surface of the epoxy resin.

In some embodiments, an unclosed opening of the conductor tape is within 10 cm.

In some embodiments, the first shielding layer is a semi-conductive tape, and the second shielding layer is a semi-conductive coating.

The present inventive concept further provides a method for constructing a transformer winding, including: determining the position having the minimum value of the leakage flux as an attachment position of the conductor tape based on a surface flux distribution of the first insulating layer; obtaining a surface potential distribution of the first shielding layer between two terminals of the conductor tape under different opening widths of the conductor tape based on a finite element analysis method or a numerical analysis calculation method and based on a dielectric constant and conductivity of the first shielding layer, a thickness of the first insulating layer, a thickness of the second insulating layer, and a dielectric constant of the second insulating layer; and obtaining a difference between a maximum value and a minimum value of the potential distribution based on the surface potential distribution of the first shielding layer; and if the difference is less than an upper limit threshold, further increasing the opening width until the difference approaches the upper limit threshold, to obtain a maximum opening width.

According to the transformer winding and the method for constructing a transformer winding of the present inventive concept, the conductor tape is attached in a surrounding manner to the surface of the first insulating layer and located at the position of the minimum value of the leakage flux, thereby greatly reducing the length of the conductor tape and reducing losses.

### BRIEF DESCRIPTION OF THE DRAWINGS

FIG. 1 illustrates a schematic diagram of a structure of a transformer winding in the prior art.

FIG. 2 illustrates a cross-sectional schematic diagram of the transformer winding in FIG. 1.

FIG. 3 illustrates a schematic diagram of a conductor tape and a cross-section thereof.

FIG. 4A illustrates a simulation diagram of a leakage flux density along a first insulating layer.

FIG. 4B illustrates a position having a minimum leakage flux density in a cross-section of a transformer winding.

FIG. 5 illustrates a schematic diagram of a transformer winding according to some embodiments of the present inventive concept.

FIG. 6 illustrates a flowchart of a method for constructing a transformer winding according to some embodiments of the present inventive concept.

### DETAILED DESCRIPTION

In order to make the objectives, technical solutions and advantages of the present inventive concept clearer, the following further describes the present inventive concept in detail in conjunction with the accompanying drawings through specific embodiments. It should be noted that the embodiments provided in the present inventive concept are only for illustration and do not limit the protection scope of the present inventive concept.

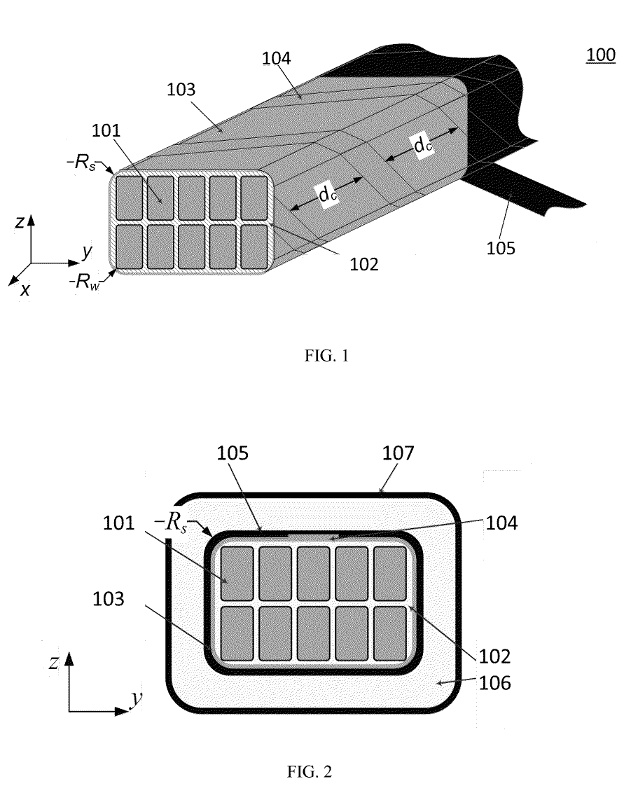

A transformer includes an iron core and a transformer winding nested on the iron core. FIG. 1 illustrates a schematic diagram of a structure of a transformer winding in the prior art, and FIG. 2 illustrates a cross-sectional schematic diagram of the transformer winding in FIG. 1. As shown in FIG. 1 and FIG. 2, the transformer winding includes a winding conductor 101, a first insulating layer 103, a conductor tape 104, a first shielding layer 105, a second insulating layer 106, and a second shielding layer 107. The first insulating layer 103 is wrapped on a surface of the winding conductor 101 formed by winding, the conductor tape 104 is wound and attached to a surface of the first insulating layer 103 in a head-tail disconnected spiral structure manner, and the first shielding layer 105 is tightly attached to the surface of the first insulating layer 103 with the conductor tape 104 attached thereto to form a preformed body 100 as shown in FIG. 1. The second insulating layer 106 is an insulating material casting layer, which is vacuum cast outside the preformed body 100. The second shielding layer 107 is tightly wrapped on an outer surface of the second insulating layer 106.

The conductor tape 104 and the first shielding layer 105 form an inner shielding layer, and the second shielding layer 107 forms an outer shielding layer.

In some embodiments, the winding conductor 101 is made of a conductor material, which includes but is not limited to a Litz wire, a copper foil, or an enameled flat wire.

In some embodiments, the first insulating layer 103 includes an insulating tape, such as an insulating paper tape or an insulating adhesive tape, including but not limited to a NOMEX paper tape, a mica tape, and a fiberglass tape, and the insulating tape is semi-overlap wound on the surface of the winding conductor to form the first insulating layer. In some embodiments, the first insulating layer 103 further includes an internal epoxy resin 102, and the internal epoxy resin 102 is coated on the outside of the winding conductor 101 to provide insulation between the winding conductor 101. The internal epoxy resin 102 is located between the winding conductor 101 and the insulating tape.

In some embodiments, the conductor tape 104 is a copper foil tape or aluminum foil tape with adhesion, which is constructed as an unclosed spiral structure with a screw pitch of dc. The conductor tape 104 is used for providing a stable potential connection for a semi-conductive layer.

In some embodiments, the first shielding layer 105 is a semi-conductive tape, preferably a semi-conductive wrinkled paper tape, and the wrinkled paper tape is semi-overlap wound on the surface of the first insulating layer 103 with the adhesive conductor tape 104 attached thereto after being stretched.

In some embodiments, the insulating material of the second insulating layer 106 is an insulating casting material, which includes but is not limited to epoxy resin and insulating silicone gel.

In some embodiments, the second shielding layer 107 may be a semi-conductive coating coated on the outer surface of the second insulating layer 106. The second shielding layer 107 is a ground coating layer.

The inventor realized through research that the electrical resistivity of the first insulating layer 103 and the second insulating layer 106 (such as epoxy resin) are very high (about 1015 Ω·m), and almost no ohmic loss occurs. The first shielding layer 105 has a high electrical resistivity (about 103 Ω·m), and eddy current losses under magnetic leakage can be ignored. Therefore, the inventor realized that the additional loss caused by the shielding layer mainly comes from the eddy current loss of the conductor tape 104 under high-frequency magnetic leakage.

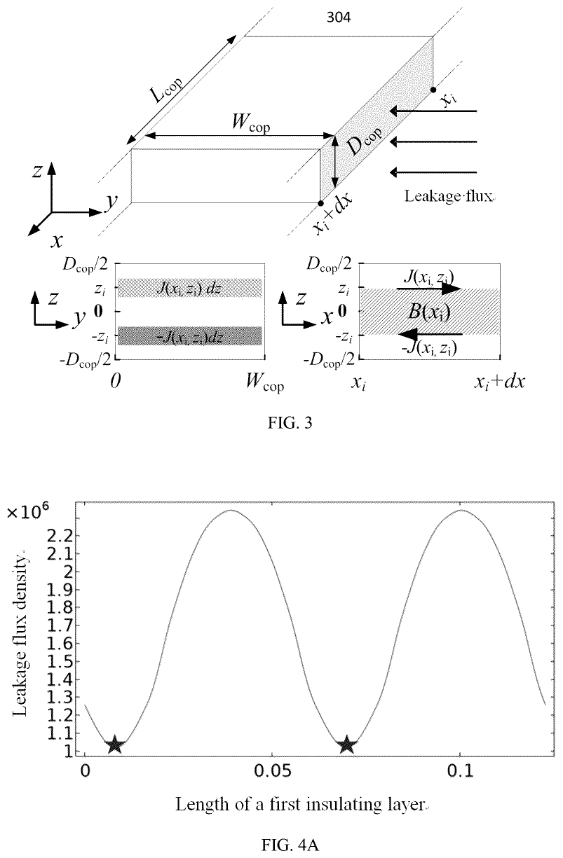

FIG. 3 illustrates a schematic diagram of a conductor tape and a cross-section thereof. The following, combined with FIG. 3, further illustrates the loss of the conductor tape.

If one end of the conductor tape is defined as a starting point, namely, a displacement point 0, the conductor tape 304 having a length of dx at the displacement point xi from the starting point of the conductor tape is shown in FIG. 3, where the x direction is a direction along the length of the conductor tape 304, the y direction is a direction along the width of the conductor tape 304, and the z direction is a direction along the thickness of the conductor tape. The conductor tape has a thickness of Dcop, a width of Wcop, a length of Lcop, and a leakage flux intensity of Bxi. A midpoint of the thickness of the conductor tape 304 is defined as point 0 in the z direction, and the electric field intensity of a vortex electric field having a thickness of zi can be obtained:

$${∮}_{l} {E}_{( {x}_{i} , {z}_{i} )} \cdot dl = - \int {\int }_{S} 〈 \overline{( \frac{\partial {B}_{{x}_{i}}}{\partial t} )} 〉 dS \qquad ( 1 )$$

The boundary perimeter l of a calculated region can be expressed as:

$$l = 4 {z}_{i} + 2 dx \qquad ( 2 )$$

The area S of the calculated region can be expressed as:

$$S = 2 {z}_{i} * dx \qquad ( 3 )$$

The vortex current density J₍ₓ_{ᵢ}_{,z}_{ᵢ}₎ generated by the vortex electric field E₍ₓ_{ᵢ}_{,z}_{ᵢ}₎ is:

$${J}_{( {x}_{i} , {z}_{i} )} = {E}_{( {x}_{i} , {z}_{i} )} \cdot {σ}_{cop} \qquad ( 4 )$$

where σ_{cop} is the conductivity of the conductor tape.

From formulas (1)-(4), the following can be obtained:

$${J}_{( {x}_{i} , {z}_{i} )} = 〈 \overline{( \frac{\partial {B}_{{x}_{i}}}{\partial t} )} 〉 \cdot {z}_{i} \cdot {σ}_{cop} \qquad ( 5 )$$

The total loss Ploss of the conductor tape calculated based on the current density J₍ₓ_{ᵢ}_{,z}_{ᵢ}₎ and the volume resistivity of the conductor tape is:

$${P}_{loss} = 2 {\int }_{0}^{{L}_{cop}} {\int }_{0}^{{D}_{cop} / 2} \frac{{{J}^{2}}_{( {x}_{i} , {z}_{i} )} \cdot {{W}^{2}}_{cop}}{{σ}_{cop} \cdot {W}_{cop}} dzdx = \frac{{σ}_{cop} \cdot {W}_{cop} \cdot {D}_{cop}^{3}}{12} {\int }_{0}^{{L}_{cop}} 〈 \overline{{( \frac{\partial {B}_{{x}_{i}}}{\partial t} )}^{2}} 〉 dx \qquad ( 6 )$$

From formula (6), it can be seen that the loss can be reduced by reducing the length of the conductor tape and reducing the leakage flux density.

If the leakage flux on the conductor tape is constant, formula (6) can be simplified as follows:

$${P}_{loss} = \frac{{σ}_{cop} \cdot {W}_{cop} \cdot {{D}^{3}}_{cop} \cdot {σ}_{cop}}{32} \cdot {( \frac{\partial B}{\partial t} )}^{2} \qquad ( 7 )$$

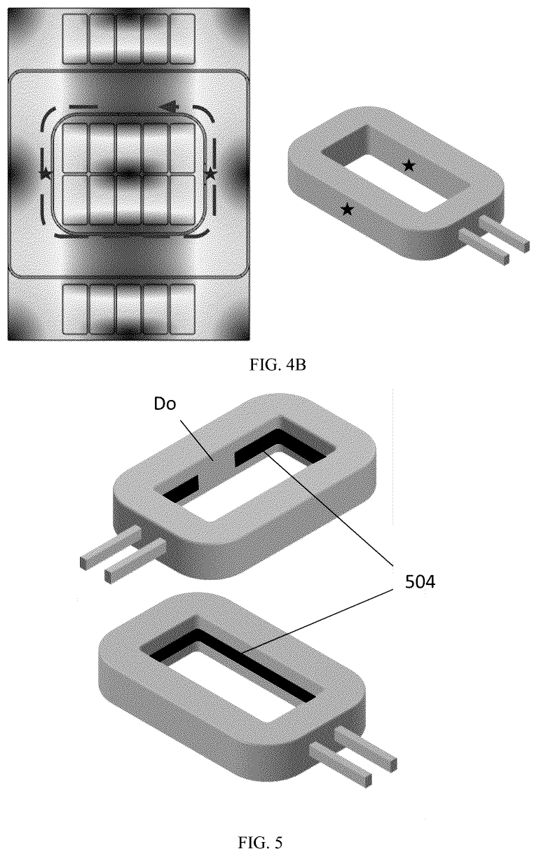

FIG. 4A illustrates a simulation diagram of a leakage flux density along the first insulating layer, with the horizontal axis representing the length of the cross-section along the first insulating layer and the vertical axis representing the leakage flux density, and the pentagram in the figure represents a minimum leakage flux density. FIG. 4B illustrates a position having a minimum leakage flux density in a cross-section of a transformer winding. It can be seen from FIG. 4B that the minimum leakage flux density is located on the inner and outer sides of the ring winding. Meanwhile, due to the smaller length of the inner conductor tape, configuring the conductor tape on the inner side of the ring winding results in lower loss.

Based on the above content, the present inventive concept provides a transformer winding, which has a ring structure and includes a winding conductor; a first insulating layer wrapped on a surface of the winding conductor formed by winding; a conductor tape attached in an unclosed surrounding manner to a surface of the first insulating layer along a circumferential direction of the first insulating layer, where the conductor tape is attached to a position having a minimum value of a leakage flux on the surface of the first insulating layer; a first shielding layer attached to the surface of the first insulating layer with the conductor tape attached thereto; a second insulating layer vacuum cast outside the first shielding layer; and a second shielding layer tightly wrapped on an outer surface of the second insulating layer. Because the conductor tape is attached in a surrounding manner to the surface of the first insulating layer and located at the position of the minimum value of the leakage flux, the length of the conductor tape is greatly reduced, and the loss is reduced.

Those skilled in the art should understand that in the present inventive concept, the term “ring” is used for describing a closed coil structure with a hollow portion in a circular or non-circular form. In the present inventive concept, the term “attached in a surrounding manner” refers to being attached circumferentially along the ring structure.

FIG. 5 illustrates a schematic diagram of a transformer winding according to some embodiments of the present inventive concept. The conductor tape 504 is attached in an unclosed surrounding manner to an inner surface of the ring structure of the first insulating layer. In some embodiments, the opening width Do of the conductor tape is within 10 cm. In these embodiments, the conductor tape has a minimum length and a minimum value of the leakage flux, and therefore its loss is minimum.

In some embodiments, the conductor tape is attached in an unclosed surrounding manner to an outer surface of the ring structure of the first insulating layer.

In some embodiments, the opening width Do of the conductor tape is obtained by the following steps:
Step 101: Obtain surface potential distribution of the first shielding layer between two terminals of the conductor tape (namely, at the opening width Do) under different opening widths Do of the conductor tape based on a finite element analysis method or a numerical analysis calculation method and based on a dielectric constant εs and conductivity ρs of the first shielding layer, a thickness Diso1 of the first insulating layer, a thickness Diso2 of the second insulating layer, and a dielectric constant εiso of the second insulating layer;
Step 102: Obtain a difference ΔV between a maximum value and a minimum value of the potential distribution based on the surface potential distribution of the first shielding layer; if the difference ΔV is less than an upper limit threshold, further increase the opening width Do until the difference ΔV approaches the upper limit threshold, to obtain a maximum opening width Do.

Table 1 shows a comparison of losses of transformer windings based on the original structure shown in FIG. 1 and the novel structure shown in FIG. 5. From Table 1, it can be seen that the transformer winding structure shown in FIG. 5 can reduce losses.

TABLE 1
Comparison of losses of transformer windings
with original and novel structures

| Frequency | Original structure | | Novel structure | | Loss reduction |
|---|---|---|---|---|---|
| 30 kHz | 26.04 | mΩ | 19.45 | mΩ | 25% |
| 90 kHz | 81.55 | mΩ | 55.17 | mΩ | 32% |
| 150 kHz | 126.37 | mΩ | 91.24 | mΩ | 27% |
| 210 KHz | 204.73 | mΩ | 166.92 | mΩ | 18% |
| Total loss | 291 | W | 214 | W | 26% |

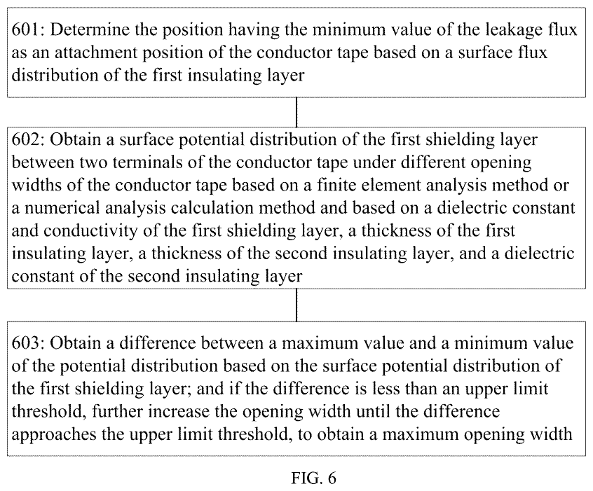

The present inventive concept further provides a method for constructing a transformer winding. FIG. 6 illustrates a flowchart of the method. The method includes:
Step 601: Determine the position of the minimum value of the leakage flux as an attachment position of the conductor tape based on a surface flux distribution of the first insulating layer, and select a shortest path as an attachment path when the minimum value of the leakage flux is distributed at a plurality of positions;
Step 602: Obtain a surface potential distribution of the first shielding layer between two terminals of the conductor tape (namely, at the opening width Do) under different opening widths Do of the conductor tape based on a finite element analysis method or a numerical analysis calculation method and based on a dielectric constant εs and conductivity ρs of the first shielding layer, a thickness Diso1 of the first insulating layer, a thickness Diso2 of the second insulating layer, and a dielectric constant iso of the second insulating layer;
Step 603: Obtain a difference ΔV between a maximum value and a minimum value of the potential distribution based on the surface potential distribution of the first shielding layer; if the difference ΔV is less than an upper limit threshold, further increase the opening width Do until the difference ΔV approaches the upper limit threshold, to obtain a maximum opening width Do.

According to the transformer winding and the method for constructing a transformer winding of the present inventive concept, the conductor tape is attached in a surrounding manner to the surface of the first insulating layer and located at the position of the minimum value of the leakage flux, thereby greatly reducing the length of the conductor tape and reducing losses.

Although the present inventive concept is described through preferred embodiments, the present inventive concept is not limited to the embodiments described herein, but further includes various changes and variations made without departing from the scope of the present inventive concept.

What is claimed is:

1. A transformer winding, comprising:
a winding conductor having a ring structure;
a first insulating layer wrapped on a surface of the winding conductor formed by winding;
a conductor tape attached in an unclosed surrounding manner to a surface of the first insulating layer along a circumferential direction of the first insulating layer, wherein the conductor tape is attached to a position having a minimum value of a leakage flux on the surface of the first insulating layer;
a first shielding layer attached to the surface of the first insulating layer with the conductor tape attached thereto;
a second insulating layer cast outside the first shielding layer; and
a second shielding layer wrapped on an outer surface of the second insulating layer.

2. The transformer winding of claim 1, wherein a shortest path with a minimum leakage flux on the surface of the first insulating layer is selected as an attachment path.

3. The transformer winding of claim 2, wherein the conductor tape is attached to an inner surface of the first insulating layer.

4. The transformer winding of claim 1, wherein the conductor tape is attached to an outer surface of the first insulating layer.

5. The transformer winding of claim 1, wherein a loss of the conductor tape is:
$${P}_{loss} = \frac{{σ}_{cop} \cdot {W}_{cop} \cdot {D}_{cop}^{3}}{12} {\int }_{0}^{{L}_{cop}} 〈 \overline{{( \frac{\partial {B}_{{x}_{i}}}{\partial t} )}^{2}} 〉 dx$$
wherein σ_{cop} is a conductivity of the conductor tape, W_{cop} is a width of the conductor tape, D_{cop} is a thickness of the conductor tape, L_{cop} is a length of the conductor tape, an Bₓ_{ᵢ} is a leakage flux intensity at a position of the conductor tape.

6. The transformer winding of claim 1, wherein the conductor tape is a copper foil tape or aluminum foil tape with adhesion.

7. The transformer winding of claim 1, wherein the first insulating layer comprises an epoxy resin coated on an outside of the winding conductor and an insulating tape semi-overlap wound on a surface of the epoxy resin.

8. The transformer winding of claim 1, wherein an unclosed opening of the conductor tape is within 10 cm.

9. The transformer winding of claim 1, wherein the first shielding layer is a semi-conductive tape, and the second shielding layer is a semi-conductive coating.

10. A method for constructing the transformer winding according to claim 1, comprising:
determining the position having the minimum value of the leakage flux as an attachment position of the conductor tape based on a surface flux distribution of the first insulating layer;
obtaining a surface potential distribution of the first shielding layer between two terminals of the conductor tape under different opening widths of the conductor tape based on a finite element analysis method or a numerical analysis calculation method and based on a dielectric constant and conductivity of the first shielding layer, a thickness of the first insulating layer, a thickness of the second insulating layer, and a dielectric constant of the second insulating layer; and
obtaining a difference between a maximum value and a minimum value of the potential distribution based on the surface potential distribution of the first shielding layer; and if the difference is less than an upper limit threshold, further increasing the opening width until the difference approaches the upper limit threshold, to obtain a maximum opening width.
